(19) United States
(12) Patent Application Publication
(10) Pub. No.: US 2026/0309803 A1
(43) Pub. Date: Oct. 8, 2026

(54) METHOD AND COMPUTER PROGRAM FOR DETECTING A SHORT-CIRCUIT IN A POWER CONVERTER, CONTROLLER FOR CONTROLLING A POWER CONVERTER, AND COMPUTER-READABLE MEDIUM

(71) Applicant: ABB Schweiz AG, Baden (CH)

(72) Inventors: Manuel Vetterli, Basel (CH); Paula Diaz Reigosa, Zürich (CH); Stefan Abrach, Wald Zh (CH); Matthias Luescher, Gontenschwil (CH)

(21) Appl. No.: 19/490,198

(22) PCT Filed: Apr. 30, 2024
(86) PCT No.: PCT/EP2024/061839

§ 371 Date: Dec. 4, 2025

(30) Foreign Application Priority Data
Jun. 6, 2023 (EP) 23177505.7

(51) Int. Cl. G01R 31/52; G01R 19/165; G01R 31/42; H02M 1/00; H02M 1/32; H02M 7/487; H02M 7/537

(52) U.S. Cl. CPC G01R 31/52; G01R 19/16571; G01R 31/42; H02M 1/0009; H02M 1/32; H02M 7/487; H02M 7/537

(57) ABSTRACT

A method for detecting a short-circuit (18) in a power converter (20) is provided. The power converter (20) comprises a first DC terminal (22), a second DC terminal (24), an AC terminal (26), a first semiconductor switch (S1) electrically coupled to the first DC terminal (22) and the AC terminal (26), a second semiconductor switch (S2) electrically coupled to the second DC terminal (24) and the AC terminal (26), and an inductance. The method comprises: sending a turn-on signal (ON) to the first semiconductor switch (S1) for turning on the first semiconductor switch (S1) and a turn-off signal (OFF) to the second semiconductor switch (S2) for turning off the second semiconductor switch (S2); receiving a voltage signal which is representative for a switch voltage (v_{S1}, V_{S2}) measured over the first semiconductor switch (S1) and the second semiconductor switch (S2);
determining an inductance voltage (V_{L}) over the inductance depending on the measured switch voltage (v_{S1}, V_{S2}) and a DC voltage (V_{DC}) between the first and second DC terminals (24); determining a current (i_{Sc}) flowing through the semiconductor switches (S1, S2) depending on the determined inductance voltage (V_{L}); and determining that the short-circuit (18) is present depending on a predetermined current threshold.

### CROSS-REFERENCE TO RELATED APPLICATIONS

This application is a national phase entry of International Patent Application No. PCT/EP2024/061839, filed on Apr. 30, 2024, and titled “METHOD AND COMPUTER PROGRAM FOR DETECTING A SHORT-CIRCUIT IN A POWER CONVERTER, CONTROLLER FOR CONTROLLING A POWER CONVERTER, AND COMPUTER-READABLE MEDIUM”, which claims priority to European Patent Application No. 23177505.7, filed Jun. 6, 2023 and titled “METHOD AND COMPUTER PROGRAM FOR DETECTING A SHORT-CIRCUIT IN A POWER CONVERTER, CONTROLLER FOR CONTROLLING A POWER CONVERTER, AND COMPUTER-READABLE MEDIUM”, the entire contents of which are hereby incorporated by reference.

### TECHNICAL FIELD

The present disclosure relates to the field of power converters and more particularly to the field of Power Electronic Converters (PECs) for motor drives or wind converters. In particular, the present disclosure relates to a method and a computer program for detecting a short-circuit in a power converter, to a controller for controlling the power converter, and to a computer-readable medium on which the computer program is stored.

### BACKGROUND

One of the most well-known multilevel conversion architectures, especially in medium voltage drive applications, is the Neutral Point Clamped (NPC) converter topology. The main advantages of this topology include modularity and scalability to different voltage and power levels, high efficiency, and low harmonic distortions in the output voltages. For reasons of simplicity, a phase of a two-level converter using IGBTs connected to a DC link capacitor is used for this description. However, the following present disclosure is generic in nature and can be extended to multi-level topologies, for example to a 3L-ANPC topology.

The reliability of such converters is one of the challenges that needs to be addressed, since medium-voltage multilevel converters have typically many semiconductor switches arranged in series and/or in parallel to increase either the voltage or, respectively, the current levels. By increasing the rated power of the converter, the number of power semiconductors may also be increased and thus, the reliability of the whole system may decrease. Any electrical fault, such as a short-circuit fault, may cause the malfunction of the whole medium-voltage system drive or even a catastrophic failure when the system does not include effective detection/protection functions. Therefore, the converter should be designed to have an effective fault-detecting method. Therefore, some modern PECs implement a protection concept to prevent hazards to persons and to minimize or limit equipment damage in case of a fault.

One important fault case is the short-circuit, in which the current starts to build up uncontrollably due to a breakdown of insulation, such as a “flashover”, or breakdown of a component of the converter, such as a loss of blocking capability of an IGBT. For example, consider a case in which an AC output of the exemplary phase of the two-level converter is shorted to one of the corresponding DC-supplies of the converter because of a fault in a semiconductor switch coupling the AC output to the corresponding DC-supply. When the output is coupled to the other DC-supply by turning off the faulted semiconductor switch and by turning on the other semiconductor switch of that phase, a short-circuit current starts to build up. It may be vital to detect this short-circuit condition quickly and reliably to limit the effects of the short-circuit and to not cause any cascading failures to neighboring power components or circuits of the same power converter or another electronic component.

Different short-circuit detection methods are already known. For example, a direct measurement of the current may be performed using one or more shunts, current transducers, or Rogowski coils; by monitoring a voltage drop across one or more parasitic inductances such as the emitter inductance in IGBT modules; or by employing desaturation detection in IGBTs and similar techniques. However, in most fault-detecting methods, additional components have to be added to the circuitry of the corresponding converter, which adds complexity. This may contribute to high cost and/or may reduce reliability of the converter.

Other approaches are based on end-of-life estimation models of electronic components of the power converter, such as capacitors and power semiconductors, to be able to predict failures before they occur. This approach may help identify weak points of the power converter and may enable the scheduling of maintenance periods. However, the converter still needs to include a method to detect and react on faults.

Many methods have been published in the literature as fault-tolerant solutions for power electronic systems. For example, a detection and protection of the semiconductor devices via the corresponding gate drive, diagnostic solutions for medium-voltage drive systems with a lower number of power semiconductor devices, and a larger number of fault-tolerant control strategies for medium-voltage drives. However, the problem is that the available solutions are difficult to be implemented for medium-voltage drive applications with a larger number of components. The common problems are either because too many sensors are used and the data is difficult to handle, or the measured data is too heavy to be transferred through the communication protocols and subsequently processed.

An example of this problem is the detection of a power semiconductor short-circuit fault, which is typically based on the well-known desaturation protection circuit integrated in the gate driver. An on-state voltage of the semiconductor device is measured and compared to a defined threshold value to determine if a short-circuit fault exists. This solution is perfect when the aim is to protect a single device, but in the case of a medium-voltage NPC converter with several semiconductor devices in series/parallel, this solution has to be combined with another method to be able to detect and protect the drive in typically less than 10 μs, which may be a typical short-circuit withstanding time of such semiconductor devices such as IGBTs and MOSFETs). This is where the present disclosure of the presented patent has raised with the aim of proposing a practicable solution that could be implemented to protect not only a single semiconductor switch but the medium-voltage drive system.

US 2012/206841 A1 describes an integrated fault current protection for power converters, in which a sensed voltage across a di/dt reactor in a phase leg of the power converter is utilized as a basis for determining the current in the phase leg and triggering a current crowbar if a threshold level for the current is reached. The di/dt reactor includes an inductive element. First, the voltage across the di/dt reactor is measured. Then, the measured voltage is converted to a current, wherein such a measurement may include integrating the voltage over a specified time period. Finally, the current is compared to a threshold and when the threshold is exceeded, the crowbar is activated.

U.S. Pat. No. 6,304,472 B1 describes a short-circuit protective circuit. An output from the integrating circuit is compared with a command value by a comparing circuit. When the current exceeds the command value, the comparing circuit outputs an OFF pulse, and a switching circuit outputs an OFF pulse to a driving circuit. The driving circuit decreases the gate voltage of the IGBT to turn off the IGBT.

US 2009/251831 A1 describes a method of identifying a short-circuit portion. For IGBT elements Q3 to Q8 forming the U-phase, V-phase and W-phase, voltage sensors for detecting collector-emitter voltages are provided. The voltage sensors detect collector-emitter voltages of the corresponding IGBT elements and output the voltages to the short-circuit portion identifying unit in the controller. Receiving the collector-emitter voltages from voltage sensors, the short-circuit portion identifying unit determines whether each of the collector-emitter voltages is equal to or higher than a prescribed threshold value. Here, the short-circuit portion identifying unit determines, in response to a determination that any of the collector-emitter voltages remains lower than the threshold voltage continuously for a prescribed time period, that the IGBT element (that is, IGBT element Q3) corresponding to the collector-emitter voltage is short-circuited.

### BRIEF DESCRIPTION

It is an objective of the present disclosure to provide a method for detecting a short-circuit in a power converter, which may contribute to protecting the entire power converter, may enable detection of the short-circuit before the power converter is damaged, and/or may be carried out in a cost-effective and/or easy way. It is an objective of the present disclosure to provide a controller for a power converter, with the controller carrying out the method. Furthermore, it is an object of the present disclosure to provide a computer program for detecting a short-circuit in a power converter, with the computer program reflecting the activities of the method, and a computer-readable medium on which the computer program is stored. These objectives are achieved by the subject-matter of the independent claims. Further exemplary embodiments are evident from the dependent claims and the following description.

In particular, an objective of the present disclosure is achieved by a method for detecting a short-circuit in a power converter. The power converter comprises a first DC terminal, a second DC terminal, an AC terminal, a first semiconductor switch electrically coupled to the first DC terminal and the AC terminal, a second semiconductor switch electrically coupled to the second DC terminal and the AC terminal, and an inductance. The method comprises receiving a voltage signal which is representative for a switch voltage measured over the first semiconductor switch and the second semiconductor switch; determining an inductance voltage over the inductance depending on the measured switch voltage and a DC voltage between the first and second DC terminals; determining a current flowing through the semiconductor switches depending on the determined inductance voltage; and determining that the short-circuit is present depending on the determined current and a predetermined current threshold.

The DC voltage may be known or measured in advance. The DC voltage may be fixed or variable. The DC voltage is nonzero while the method is carried out. When the DC voltage is zero, the power converter does not operate and may be shut down. Before starting the above method, one of the semiconductor switches may be turned on and the other one may be turned off. For example, a turn-on signal may be sent to one of the semiconductor switches, such as to the first semiconductor switch, for turning on the corresponding semiconductor switch and a turn-off signal may be sent to the other one of the semiconductor switches, such as to the second semiconductor switch, for turning off the corresponding semiconductor switch.

The power converter may comprise a DC link coupling the DC terminals to each other via a DC capacitor. One of the DC terminals may be a DC-terminal and the other one of the DC terminals may be a DC+ terminal. The semiconductor switches may be directly coupled to the AC terminal or via another converter stage of the power converter. The power converter may comprise a clamp circuit, for example a di/dt clamp circuit. The power converter may comprise one or more further semiconductor switches, DC links, clamp circuits, and/or a neutral point terminal, such as between two of the DC links. The power converter may be referred to as Power Electronic Converter (PEC). The power converter may be Neutral Point Clamped (NPC) converter, a half-bridge, a single phase of a two-level converter, a complete two-level converter, or a 3L-ANPC converter.

The first and/or second semiconductor switch each may be an Insulated-Gate Bipolar Transistor (IGBT). At least one of the semiconductor switches may be a high-power semiconductor switch and may be referred to as power semiconductor chip.

The inductance may be a parasitic inductance, comprising one or more electric lines of the power converter, and/or a dedicated inductance component, such as an inductor, a di/dt limiting inductor, or a coil. In the former case, the inductance component may be omitted. This may contribute to a cost-efficiency, simplicity, and high reliability of the power converter. In any case, an inductance value of the inductance may be known in advance, for example, by providing an inductance component with a known inductance value and/or by measuring the parasitic inductance. The inductance component may be connected to a DC link capacitor of the DC link.

The present disclosure provides an indirect method to detect the short-circuit by supervising the voltage that is applied on the inductance in the commutation path. This short-circuit detection method may be applicable to a broad range of PECs, not limited to a specific topology or semiconductor technology, scaling with voltage and current of the PEC, having low implementation effort basing on existing measurements and circuits present in a typical PEC and thus not compromising the overall reliability. Furthermore, in PECs using IGBTs, short-circuit detection may be possible before the device enters the desaturation region, reducing the peak power and thus thermal stress on the device. Further, early detection of short-circuits allows turn-off sequences to be initiated at lower fault current levels compared to traditional DESAT detection methods, resulting in a faster and more reliable fault containment.

According to an embodiment, the voltage signal, which is representative for the switch voltage, is representative for a first switch voltage and a second switch voltage. This enables the determination of the contribution of the first and second semiconductor switches to the switch voltage. For example, the voltage signal may be representative for a sum of the first and second switch voltages. The first and second switch voltages may be measured.

According to an embodiment, when determining the inductance voltage over the inductance depending on the measured switch voltage and the DC voltage, the switch voltages are added together, the corresponding sum is subtracted from the DC voltage, and the difference is determined as the inductance voltage. This contributes to determining the inductance voltage over the inductance in an easy way.

According to an embodiment, when determining the current flowing through the semiconductor switches depending on the determined inductance voltage, the difference is integrated over the time and the corresponding integral is determined as the current. For example, the voltage-time-area over the inductance may be integrated. The integration enables the calculation of a short-circuit current. When integrating the difference over the time, the difference or the integral may be divided by the inductance value, if the inductance value is constant. Otherwise, in case of the inductance value not being constant, the difference may be divided by the inductance value and this quotient may be integrated, wherein the corresponding integral may be the short-circuit current.

According to an embodiment, when it is determined that the short-circuit may be present, the short-circuit is confirmed as present if the determined current reaches or exceeds a predetermined current threshold. The predetermined current threshold may be predetermined by a manufacturer of the power converter. The predetermined current threshold may be that current until which the semiconductor switches are not damaged, at least for a short period of time.

According to an embodiment, a reference DC voltage signal is sent to an energy source coupled to the DC terminals, wherein the energy source provides the DC voltage to the DC terminals upon receiving the reference DC voltage signal. In this case, the reference DC voltage signal may be representative for the DC voltage and the DC voltage may be referred to as reference DC voltage or DC voltage reference. Alternatively or additionally, a second DC voltage signal is received before determining the inductance voltage, wherein the second DC voltage signal is representative for the DC voltage and wherein the second DC voltage signal is determined from a voltage measurement. In this case, the DC voltage may be measured directly, such as at the DC link, or the switch voltages may be measured and the DC voltage may be derived from the measured switch voltages. For example, a mean value of the inductance voltage can be assumed to be zero. Therefore, a mean value or low pass filtered value of the sum of the switch voltages may correspond to the DC-voltage. So, if it is not the case already, the power converter should be supplied with energy in the form of DC voltage before carrying out the above method.

According to an embodiment, the parasitic inductance is an inductance component of the power converter. For example, the inductance component may be an inductor, such as a di/dt limiting inductor or a coil. The inductance component may be arranged in the commutation path of the power converter, for example, between one of the semiconductor switches such as the first semiconductor switch, and the DC-terminal to which the corresponding semiconductor switch is coupled. For example, if the power converter comprises the clamp circuit, the inductance component may be a part of the clamp circuit.

An objective is achieved by another method for detecting the short-circuit in the power converter. The power converter may correspond to the above power converter. For example, the power converter again comprises the first DC terminal, the second DC terminal, the AC terminal, the first semiconductor switch electrically coupled to the first DC terminal and the AC terminal, the second semiconductor switch electrically coupled to the second DC terminal and the AC terminal, and the inductance. The method comprises receiving a voltage signal which is representative for the switch voltage measured over the first semiconductor switch and the second semiconductor switch; determining whether the switch voltage does not exceed a given forward voltage of the semiconductor switches; when the switch voltage does not exceed the given forward voltage, determining a duration during which the switch voltage does not exceed the given forward voltage; and determining that the short-circuit is present when the determined duration reaches or exceeds a duration threshold. When it is determined that the switch voltage does exceed the given forward voltage of the semiconductor switches, it may be determined that no short-circuit is present. The given forward voltage may be a normal and/or specific forward voltage of the semiconductor switches.

Determining the duration and determining that the short-circuit is present when the determined duration reaches or exceeds a duration threshold is based on the insight of the inventors that when neither the first semiconductor switch nor the second semiconductor switch see any voltage, it can be concluded that the DC voltage is applied over the inductance. In this case, the current through the semiconductor switches is proportional to the DC voltage and the duration during which the voltage is present, and inversely proportional to the inductance value of the inductance. In turn and keeping in mind that the DC voltage and the inductance value are known in advance or by measurement, the duration threshold may be easily determined depending on the predetermined current threshold, and it is sufficient to measure the duration only and to compare it with the duration threshold.

Therefore, in the context of the first aspect described above, the method according to the second aspect comprises the activity of determining the inductance voltage over the parasitic inductance, based on the measured switch voltage and the DC voltage, by recognizing that the switch voltage does not exceed the given forward voltage of the semiconductor switches and by setting the inductance voltage as the DC voltage. Further, in this case, the duration is representative for the current, because the duration is proportional to the current and because the proportionality factor, which is the inductance value divided by the DC voltage, is known. So, both aspects are based on the same inventive idea, and the activities of the corresponding methods are the same or at least similar, wherein the method according to the second aspect may be even faster, simpler, more cost-efficient, and/or more reliable than the method according to the first aspect.

The above advantages and/or effects of the method according to the first aspect may be transferred to the method according to the second aspect. Therefore, a repetition of these advantages and/or effects is omitted and it is referred to the above explanations only in order to provide a concise description. Additionally, the physical features of the power converter according to the first aspect may be transferred to physical features of the power converter according to the second aspect. In other words, the above two methods may be carried out at the same power converter.

According to an embodiment, the duration threshold is determined by multiplying an inductance value of the inductance with a predetermined maximum fault current and by dividing the corresponding product by a DC voltage between the first and second DC terminals. The predetermined maximal fault current may correspond to the above current threshold.

According to an embodiment, the reference DC voltage signal is sent to the energy source coupled to the DC terminals, wherein the energy source provides the DC voltage to the DC terminals upon receiving the reference DC voltage signal. In this case, the reference DC voltage signal may be representative for the DC voltage and the DC voltage may be referred to as reference DC voltage or DC voltage reference. Alternatively or additionally, the second DC voltage signal is received before determining the duration threshold, wherein the second DC voltage signal is representative for the DC voltage and wherein the second DC voltage signal is determined from the voltage measurement. In this case, the DC voltage may be measured directly, such as at the DC link, or the switch voltages may be measured and the DC voltage may be derived from the measured switch voltages. For example, a mean value of the inductance voltage can be assumed to be zero. Therefore, a mean value or low pass filtered value of the sum of the switch voltages may correspond to the DC-voltage.

According to an embodiment, the inductance is the inductance component of the power converter. An objective is achieved by a controller for controlling the power converter. The controller comprises an input terminal for receiving one or more of the voltage signals; an output terminal for sending one or more control signals to the power converter; and a processor configured for carrying out at least one of the above methods.

An objective is achieved by a computer program for detecting the short-circuit in the power converter. The computer program, when executed by the processor of the controller for controlling the power converter, performs at least one of the above methods. An objective is achieved by a computer-readable medium on which the computer program is stored.

The above features, advantages and/or effects of one or both of the above methods, in particular according to the first and/or second aspects, may be transferred to the controller, the computer program, and/or the computer-readable medium, or vice versa. Therefore, a repetition of these features, advantages, and/or effects is omitted and it is referred to the above explanations only in order to provide a concise description. The above and other aspects of the present disclosure will be apparent from and elucidated with reference to the embodiments described hereinafter.

### BRIEF DESCRIPTION OF DRAWINGS

The subject matter of the present disclosure will be explained in more detail in the following text with reference to exemplary embodiments which are illustrated in the attached drawings.

FIG. 1 schematically shows a circuit diagram of an exemplary embodiment of a power converter;

FIG. 2 schematically shows a flow-chart of an exemplary embodiment of a method for detecting a short-circuit in a power converter; and

FIG. 3 schematically shows a flow-chart of another exemplary embodiment of a method for detecting a short-circuit in a power converter.

The reference symbols used in the drawings, and their meanings, are listed in summary form in the list of reference symbols. In principle, identical parts are provided with the same reference symbols in the figures.

### DETAILED DESCRIPTION

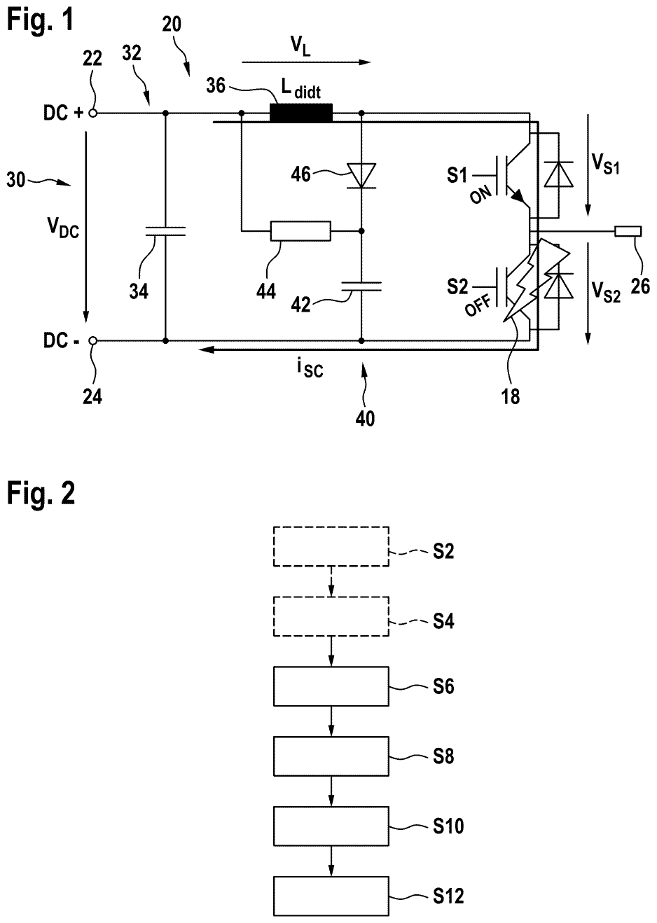

FIG. 1 schematically shows a circuit diagram of an exemplary embodiment of a power converter 20. The power converter 20 may be a Power Electronic Converter (PEC). The power converter 20 may be a part of a Neutral Point Clamped (NPC) converter, a half-bridge, a single phase of a two-level converter, a part of a complete two-level converter, or a part of a 3L-ANPC converter. The power converter 20 may be used in an inverter or rectifier. The power converter 20 may be implemented for a medium-voltage drive application.

The power converter 20 comprises a first DC terminal 22 (such as a DC+ terminal), a second DC terminal 24 (such as a DC-terminal), an output (provided by an AC terminal 26), a first semiconductor switch S1 electrically coupled to the first DC terminal 22 and the AC terminal 26, a second semiconductor switch S2 electrically coupled to the second DC terminal 24 and the AC terminal 26, and an inductance. The DC terminals 22, 24 are coupled to an energy source 30, in particular a DC energy source, such as a battery, a rectifier, an active rectifier, a solar panel, a DC grid or similar components. The semiconductor switches S1, S2 may be directly coupled to the AC terminal 26 or via another converter stage (not shown) of the power converter 20 in case of a three-level NPC or ANPC converter. The first and/or second semiconductor switches S1, S2 each may be an Insulated-Gate Bipolar Transistor (IGBT). At least one of the semiconductor switches S1, S2 may be a high-power semiconductor switch and may be referred to as power semiconductor switch.

The power converter 20 may further comprise a DC link 32 coupling the DC terminals 22, 24 to each other, via a first capacitor 34, in other words a DC capacitor. The power converter 20 may further comprise a clamp circuit 40, such as a di/dt clamp circuit. The clamp circuit 40 may comprise a second capacitor 42 and a diode 46 electrically arranged in series and electrically coupling the DC terminals 22, 24 to each other. The clamp circuit 40 may further comprise a resistor 44 coupling a node between the second capacitor 42 and the diode 46 to the first DC terminal 22.

The inductance may be a parasitic inductance, for example, comprising one or more electric lines of the power converter, and/or an inductance component 36, such as an inductor, a di/dt limiting inductor, or a coil. In the former case, the inductance component 36 may be omitted. The inductance component 36 may be connected to the first capacitor 34 of the DC link 32. The inductance component 36 may be arranged between to nodes at which the clamp circuit 40 is electrically coupled to the first DC terminal 22. The one or more electric lines forming the parasitic inductance may be a part of a commutation path of the power converter 20. The commutation path may extend from one of the DC terminals 22, 24 via the semiconductor switches S1, S2 to the other one of the DC terminals 22, 24. In any case, an inductance value of the inductance may be known in advance by arranging the inductance component 36 having the known inductance value and/or by measuring the parasitic inductance in at least a part of the commutation path.

The power converter 20 may comprise one or more further semiconductor switches, DC links, clamp circuits, and/or a neutral point terminals between two of the corresponding further DC links. In case of a fault of the power converter 20, a short-circuit 18 may be present in the power converter 20. For example, the short-circuit 18 may bypass one of the semiconductor switches S1, S2, such as the second semiconductor switch S2. In this case, the output of the power converter 20, which is the AC terminal 26 in this embodiment, may be directly coupled with the second DC terminal 24. If the first semiconductor S1 is turned on and as such electrically conductive, the first and second DC terminals 22, 24 are short-circuited by the turned-on first semiconductor switch S1 and the short-circuit 18.

In the following, two different methods which are based on the same inventive idea and possible implementations thereof are described at the example of the power converter 20. However, the proposed methods are generic in nature and can be applied to multi-level topologies like the 3L-ANPC, for example. The topology of the 3L-ANPC may be easily derived from the power converter shown in FIG. 1. In particular, for the 3L-ANPC, the power converter 20 may be duplicated wherein the double may be arranged below the power converter 20, for example, such that the commutation path from the second semiconductor switch S2 to the second DC terminal 24 is shared between the power converter 20 and the double, wherein this shared part of the commutation path forms the neutral point potential of the 3L-ANPC. Furthermore, the outputs of the power converter 20 and the double may be coupled to each other via two further semiconductor switches, wherein a node between the two further semiconductor chips may provide an AC terminal and as such an output of the 3L-ANPC.

The methods and descriptions below are based on the exemplary fault case shown in FIG. 1, namely, the two-level power converter 20 with faulted second semiconductor switch S2 (fail to short) and with the first semiconductor switch S1 turned on into the short-circuit 18. However, the proposed methods are applicable to different fault cases including but not limited to a short of an upper or lower half-bridge switch, short circuit types I, II and III, insulation failure, and output short to one of the DC-terminals 22, 24.

FIG. 2 schematically shows a flow-chart of an exemplary embodiment of a method for detecting a short-circuit in a power converter, namely, the short-circuit 18 in the above power converter 20. The method may be carried out when energy is supplied to the power converter 20 by the energy source 30. So, the method may be carried out when a DC voltage V_{DC} between the DC terminals 22, 24 is nonzero. The method may be carried out by a controller configured for controlling the power converter 20. The controller may be a part of the power converter 20 or may be external with respect to the power converter 20.

In an optional activity S2, which may be carried out when the energy is not yet supplied to the power converter 20 or when the amount of the DC voltage V_{DC} is not yet known, a reference DC voltage signal may be sent to the energy source 30 coupled to the DC terminals 22, 24. The reference DC voltage signal may be representative for the DC voltage V_{DC} and the DC voltage V_{DC} may be referred to as reference DC voltage or DC voltage reference. The energy source 30 may provide the DC voltage V_{DC} to the DC terminals 22, 24 upon receiving the reference DC voltage signal. Alternatively or additionally, a second DC voltage signal may be received before determining an inductance voltage V_{L} over the explained inductance above, namely, the inductance component 36 and/or the parasitic inductance, wherein the second DC voltage signal may be representative for the DC voltage V_{DC} and wherein the DC voltage may be derived from the measured switch voltages. The second voltage signal may be generated by a voltmeter and may be received by the controller (not shown) for controlling the power converter 20.

In an optional activity S4, a turn-on signal ON may be sent to the first semiconductor switch S1 for turning on the first semiconductor switch S1 and a turn-off signal OFF may be sent to the second semiconductor switch S2 for turning off the second semiconductor switch S2. In this situation, the short-circuit 18 short-circuits the DC terminals 22, 24 with each other.

In an activity S6, a voltage signal which is representative for a switch voltage v_{S1}, v_{S2} measured over the first semiconductor switch S1 and the second semiconductor switch S2 may be measured. For example, the voltage signal, which is representative for the switch voltage v_{S1}, v_{S2}, may be representative for a first switch voltage v_{S1} over the first semiconductor switch S1 and a second switch voltage v_{S2} over the second semiconductor switch S2.

In an activity S8, the inductance voltage V_{L} over the inductance may be determined depending on the measured switch voltage(s) v_{S1}, v_{S2} and the DC voltage V_{DC} between the first and second DC terminals 22, 24. For example, the switch voltages v_{S1}, v_{S2} may be added together, the corresponding sum may be subtracted from the DC voltage V_{DC}, and the difference may be determined as the inductance voltage V_{L} in accordance with the following formula:

$${V}_{dc} = {V}_{L} + {V}_{S 1} + {V}_{S 2} ⇔ {V}_{L} = {V}_{d c} − {V}_{S 1} − {V}_{S 2}$$

In an activity S10, a current i_{SC}, in particular a short-circuit current, flowing through the semiconductor switches S1, S2 may be determined depending on the determined inductance voltage V_{L}. For example, the difference determined in activity S8 may be integrated over the time and the corresponding integral may be determined as the current i_{SC} in accordance with the following formula:

$${i}_{SC} = \int \frac{{V}_{L} ( t )}{{L}_{didt}} d t = \int \frac{{V}_{dc} − {V}_{S 1} ( t ) − {V}_{S 2} ( t )}{{L}_{didt}} d t$$

In an activity S12, it may be determined that the short-circuit 18 is present depending on a predetermined current threshold i_{SC_max} being the maximal acceptable fault current, as shown below. For example, the short-circuit 18 may be determined as being present when the current i_{SC} determined in activity S10 reaches or exceeds the predetermined current threshold i_{SC_max}. Then, a predetermined fault reaction, for example a predetermined turn-off sequence, may be executed.

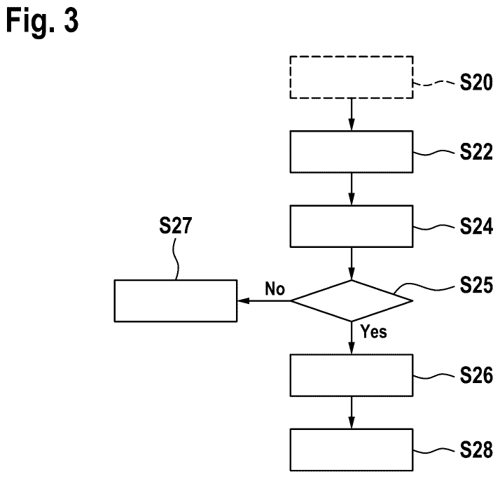

FIG. 3 schematically shows a flow-chart of another exemplary embodiment of a method for detecting a short-circuit in a power converter, namely, the short-circuit 18 of the above power converter 20. The method may be carried out when energy is supplied to the power converter 20 by the energy source 30. So, the method may be carried out when the DC voltage V_{DC} between the DC terminals 22, 24 is nonzero. The method may be carried out by a controller configured for controlling the power converter 20. The controller may be a part of the power converter 20 or may be external with respect to the power converter 20.

An optional activity S20 may correspond to the optional activity S2 explained above. An optional activity S22 may correspond to the optional activity S4 explained above. In an activity S24, a voltage signal which is representative for the switch voltages v_{S1}, v_{S2} over the first semiconductor switch S1 and the second semiconductor switch S2 may be received.

In an activity S25, it may be determined whether the switch voltages v_{S1}, v_{S2} do not exceed a given forward voltage of the semiconductor switches S1 and S2. If the condition of activity S25 is fulfilled, the method proceeds in an activity S26. If the condition of activity S25 is not fulfilled, the method proceeds in an activity S27.

The measurement of any voltage exceeding the normal forward voltage over the semiconductor switches S1, S2 may be referred to as “voltage feedback”. This voltage feedback measurement is traditionally present in power converters using IGBTs to be able to detect desaturation of the semiconductors. If neither the first semiconductor switch S1 nor the second semiconductor switch S2 see any voltage feedback, it may be concluded that the DC voltage V_{DC} is applied over the inductance, as may be seen from the formulas firstly presented above. Furthermore, assuming that the DC voltage V_{DC} is constant during a first point t₁ in time and a second point t₂ in time, the formula secondly presented above, may be simplified as:

$${i}_{SC} = \int \frac{{V}_{L} ( t )}{{L}_{didt}} d t \approx {\int }_{{t}_{1}}^{{t}_{2}} \frac{{V}_{dc}}{{L}_{didt}} d t = \frac{{V}_{dc}}{{L}_{didt}} ( {t}_{2} − {t}_{1} ) = \frac{{V}_{dc}}{{L}_{didt}} {t}_{SC}$$

with t_{SC} being the duration between the time points t₁ and t₂.

In activity S26, a duration during which the switch voltage v_{S1}, v_{S2} do not exceed the given forward voltage may be determined.

In activity S27, the method may be terminated and/or determined that no short-circuit is present.

In an activity S28, it may be determined that the short-circuit 18 is present when the determined duration reaches or exceeds a duration threshold. The duration threshold may be determined by multiplying an inductance value L_{didt} of the inductance with a predetermined maximum fault current and by dividing the corresponding product by the DC voltage V_{DC} between the first and second DC terminals 22 and 24 by the following formula:

$${t}_{SC \_ max} = \frac{{L}_{didt}}{{V}_{dc}} {i}_{SC \_ max}$$

with i_{SC_max} being the maximal acceptable fault current and thereby the predetermined current threshold. Then, the predetermined fault reaction, for example a predetermined turn-off sequence, may be executed.

While the present disclosure has been illustrated and described in detail in the drawings and foregoing description, such illustration and description are to be considered illustrative or exemplary and not restrictive; the present disclosure is not limited to the disclosed embodiments. Other variations to the disclosed embodiments can be understood and effected by those skilled in the art and practicing the claimed present disclosure, from a study of the drawings, the disclosure, and the appended claims.

In the claims, the word “comprising” does not exclude other elements or activities, and the indefinite article “a” or “an” does not exclude a plurality. A single processor or controller or other unit may fulfil the functions of several items recited in the claims. The mere fact that certain measures are recited in mutually different dependent claims does not indicate that a combination of these measures cannot be used to advantage. Any reference signs in the claims should not be construed as limiting the scope.

The disclosed systems and methods are not limited to the specific embodiments described herein. Rather, components of the systems or activities of the methods may be utilized independently and separately from other described components or activities.

1. A method for detecting a short-circuit in a power converter, the power converter comprising a first direct current (DC) terminal, a second DC terminal, an alternating current (AC) terminal, a first semiconductor switch electrically coupled to the first DC terminal and the AC terminal, a second semiconductor switch electrically coupled to the second DC terminal and the AC terminal, and an inductance, the method comprising:
receiving a voltage signal which is representative for a switch voltage measured over the first semiconductor switch and the second semiconductor switch;
determining an inductance voltage over the inductance based on the measured switch voltage and a DC voltage between the first and second DC terminals;
determining a current flowing through the semiconductor switches based on the determined inductance voltage; and
determining that the short-circuit is present based on the determined current and a predetermined current threshold.

2. The method in accordance with claim 1, wherein the voltage signal, which is representative for the switch voltage, is representative for a first switch voltage and a second switch voltage.

3. The method in accordance with claim 2, wherein, when determining the inductance voltage over the inductance based on the measured switch voltage and the DC voltage, the switch voltages are added together, the corresponding sum is subtracted from the DC voltage, and the difference is determined as the inductance voltage.

4. The method in accordance with claim 3, wherein, when determining the current flowing through the semiconductor switches based on the determined inductance voltage, the difference is integrated over the time and the corresponding integral is determined as the current.

5. The method in accordance with claim 4, wherein, when determining that the short-circuit is present based on the determined current and the predetermined current threshold, the short-circuit is determined as being present when the determined current reaches or exceeds the predetermined current threshold.

6. The method in accordance with claim 1, wherein;
a reference DC voltage signal is sent to an energy source coupled to the DC terminals, and the energy source provides the DC voltage to the DC terminals upon receiving the reference DC voltage signal; and/or
a second DC voltage signal is received before determining the inductance voltage, the second DC voltage signal is representative for the DC voltage and the second DC voltage signal is determined from a voltage measurement.

7. The method in accordance with claim 1, wherein the inductance is an inductance component of the power converter.

8. A method for detecting a short-circuit in a power converter, the power converter comprising a first DC terminal, a second DC terminal, an AC terminal, a first semiconductor switch electrically coupled to the first DC terminal and the AC terminal, a second semiconductor switch electrically coupled to the second DC terminal and the AC terminal, and an inductance, the method comprising:
receiving a voltage signal which is representative for a switch voltage measured over the first semiconductor switch and the second semiconductor switch;
determining whether the switch voltage does not exceed a given forward voltage of the semiconductor switches;
determining a duration during which the switch voltage does not exceed the given forward voltage when the switch voltage does not exceed the given forward volage; and
determining that the short-circuit is present when the determined duration reaches or exceeds a duration threshold, wherein the duration threshold is determined by:
multiplying an inductance value of the inductance with a predetermined maximum fault current; and
dividing the corresponding product by a DC voltage between the first and second DC terminals.

9. The method in accordance with claim 8, wherein:
a reference DC voltage signal is sent to an energy source coupled to the DC terminals, and the energy source provides the DC voltage to the DC terminals upon receiving the reference DC voltage signal; and/or
a second DC voltage signal is received before determining the duration threshold, the second DC voltage signal is representative for the DC voltage, and the second DC voltage signal is determined from a voltage measurement.

10. The method in accordance with claim 8, wherein the inductance is an inductance component of the power converter.

11. A controller for detecting a short-circuit in a power converter, the power converter comprising a first direct current (DC) terminal, a second DC terminal, an alternating current (AC) terminal, a first semiconductor switch electrically coupled to the first DC terminal and the AC terminal, a second semiconductor switch electrically coupled to the second DC terminal and the AC terminal, and an inductance, the controller comprising:
an input terminal for receiving one or more voltage signals;
an output terminal for sending one or more control signals to the power converter; and
at least one processor configured to:
receive a voltage signal which is representative for a switch voltage measured over the first semiconductor switch and the second semiconductor switch;
determine an inductance voltage over the inductance based on the measured switch voltage and a DC voltage between the first and second DC terminals;
determine a current flowing through the semiconductor switches based on the determined inductance voltage; and
determine that the short-circuit is present based on the determined current and a predetermined current threshold.

12. The controller in accordance with claim 11, wherein the voltage signal, which is representative for the switch voltage, is representative for a first switch voltage and a second switch voltage.

13. The controller in accordance with claim 12, wherein, to determine the inductance voltage over the inductance based on the measured switch voltage and the DC voltage, the at least one processor is further configured to:
add the switch voltages together;
subtract the corresponding sum from the DC voltage; and
determine the difference as the inductance voltage.

14. The controller in accordance with claim 13, wherein, to determine the current flowing through the semiconductor switches based on the determined inductance voltage, the at least one processor is further configured to:
integrate the difference over the time; and
determine the corresponding integral as the current.

15. The controller in accordance with claim 14, wherein, to determine that the short-circuit is present based on the determined current and the predetermined current threshold, the at least one processor is further configured to:
determine that the short-circuit as being present when the determined current reaches or exceeds the predetermined current threshold.

16. The controller in accordance with claim 15, wherein the at least one processor is further configured to:
send a reference DC voltage signal to an energy source coupled to the DC terminals, wherein the energy source provides the DC voltage to the DC terminals upon receiving the reference DC voltage signal; and/or
receive a second DC voltage signal before determining the inductance voltage, wherein the second DC voltage signal is representative for the DC voltage; and
determine the second DC voltage signal from a voltage measurement.

17. The controller in accordance with claim 13, wherein the at least one processor is further configured to:
send a reference DC voltage signal to an energy source coupled to the DC terminals, wherein the energy source provides the DC voltage to the DC terminals upon receiving the reference DC voltage signal; and/or
receive a second DC voltage signal before determining the inductance voltage, wherein the second DC voltage signal is representative for the DC voltage; and
determine the second DC voltage signal from a voltage measurement.

18. A controller for detecting a short-circuit in a power converter, the power converter comprising a first DC terminal, a second DC terminal, an AC terminal, a first semiconductor switch electrically coupled to the first DC terminal and the AC terminal, a second semiconductor switch electrically coupled to the second DC terminal and the AC terminal, and an inductance, the controller comprising at least one processor configured to:
receive a voltage signal which is representative for a switch voltage measured over the first semiconductor switch and the second semiconductor switch;
determine whether the switch voltage does not exceed a given forward voltage of the semiconductor switches;
determine a duration during which the switch voltage does not exceed the given forward voltage when the switch voltage does not exceed the given forward voltage; and
determine that the short-circuit is present when the determined duration reaches or exceeds a duration threshold, wherein, to determine the duration threshold, the at least one processor is further configured to:
multiply an inductance value of the inductance with a predetermined maximum fault current; and
divide the corresponding product by a DC voltage between the first and second DC terminals.

19. The controller in accordance with claim 18, wherein the at least one processor is further configured to:
send a reference DC voltage signal to an energy source coupled to the DC terminals, wherein the energy source provides the DC voltage to the DC terminals upon receiving the reference DC voltage signal; and/or
receive a second DC voltage signal before determining the duration threshold, wherein the second DC voltage signal is representative for the DC voltage; and
determine the second DC voltage signal from a voltage measurement.

20. The controller in accordance with claim 18, wherein:
the inductance is an inductance component of the power converter.
